(19) United States
(12) Patent Application Publication
(10) Pub. No.: US 2026/0191016 A1
(43) Pub. Date: Jul. 2, 2026

(54) SEMICONDUCTOR PACKAGE

(71) Applicant: ELSPES Inc., Daejeon (KR)

(72) Inventors: Seunggu LIM, Hwaseong-si (KR); Wisnu MURTI, Hwaseong-si (KR); Yeong Lyeol PARK, Yongin-si (KR)

(21) Appl. No.: 19/086,201

(22) Filed: Mar. 21, 2025

(30) Foreign Application Priority Data
Dec. 30, 2024 (KR) 10-2024-0201026

(51) Int. Cl. H01L 23/66; H01L 23/538; H01L 25/18; H10D 1/68

(52) U.S. Cl. CPC H10W 44/20; H10W 70/611; H10W 70/65; H10W 90/00; H10D 1/68; H10W 44/223

(57) ABSTRACT

The present invention relates to a semiconductor package. The semiconductor package of the present invention includes a package substrate, a first semiconductor die disposed on the package substrate, a second semiconductor die disposed on the package substrate to be spaced apart from the first semiconductor die, and at least one pair of differential channels connected to the first semiconductor die and the second semiconductor die, wherein the at least one pair of differential channels include at least one first differential channel and at least one second differential channel, each of which transmits a signal with a different phase, the at least one first differential channel includes a first capacitor, the at least one second differential channel includes a second capacitor, and each of the first capacitor and the second capacitor includes a first pad or bump connected to the first semiconductor die and a second pad or bump connected to the second semiconductor die, and the semiconductor package may reduce electrical non-uniformity between differential channels and ensure the symmetry and stability of differential signals by including alternating current (AC) coupling capacitors disposed in each differential channel.

### CROSS-REFERENCE TO RELATED APPLICATION

This application claims priority to and the benefit of Korean Patent Application No. 2024-0201026, filed on Dec. 30, 2024, the disclosure of which is incorporated herein by reference in its entirety.

### BACKGROUND

### 1. Field of the Invention

The present invention relates to a semiconductor package, and more particularly, to a semiconductor package including a coupling capacitor in a differential channel.

### 2. Discussion of Related Art

The recent rapid advancement of portable electronic devices, such as smartphones, tablets, and wearable devices, requires these devices to become smaller while delivering higher performance and consuming less power. Accordingly, semiconductor devices are being developed to keep up with the trend of miniaturization and high integration in electronic devices, but, in conventional multi-chip designs, issues such as increased interconnection complexity between components, data transmission delays, and higher power consumption arise.

To address these issues, a system-on-chip (SoC) in which various processing devices, including a central processing unit (CPU), a graphics processing unit (GPU), a digital signal processor (DSP), a neural processing unit (NPU), and radio frequency (RF) circuits, are integrated with a long-term evolution (LTE)/5G communication modem, memory blocks, and the like into a single chip to reduce the interconnection complexity between components while enhancing performance and power efficiency, has been proposed. However, in SoC design, there is a constraint that heterogeneous components must be manufactured in a single process. For example, some components require a 14 nm process, whereas other components can be sufficiently implemented using a 28 nm or 40 nm process. In this case, when all components are integrated using a 14 nm process, excessive resources are wasted on chips that could have been efficiently produced with a 28 nm or 40 nm process. In addition, heterogeneous components designed based on different materials require processes optimized for the characteristics of each material, and when these heterogeneous components are implemented through a single process, both manufacturing and design efficiencies decrease.

Accordingly, there is a need for technology to address the above-described issues.

Meanwhile, the above-described background art is technical information possessed by the inventor for derivation of the present invention or acquired by the inventor during the derivation of the present invention, and is not necessarily considered to be a known technology open to the general public prior to the filing of the present invention.

### PRIOR-ART DOCUMENTS

### Patent Document

(Patent Document 1) US Patent Publication No. 2013-0134607 (May 30, 2013)

### SUMMARY OF THE INVENTION

The present invention is directed to providing a semiconductor package that enables the integration and interconnection of heterogeneous chips on a single substrate.

The present invention is also directed to providing a semiconductor package that enables the integration of semiconductor dies with a higher density by including a coupling capacitor disposed in a package substrate or an interposer.

The present invention is also directed to providing a semiconductor package capable of reducing signal noise and ensuring signal integrity by disposing a coupling capacitor in each of a pair of differential channels.

The present invention is also directed to providing a semiconductor package that enables high-speed signal transmission in chip-to-chip communication while reducing cross talk and common mode noise by interconnecting a plurality of semiconductor dies through differential channels including coupling capacitors.

Objectives of the present invention are not limited to the above-described objectives, and other objectives that are not described herein will be apparently understood by those skilled in the art from the following description.

According to an aspect of the present invention, there is provided a semiconductor package including a package substrate, a first semiconductor die disposed on the package substrate, a second semiconductor die disposed on the package substrate to be spaced apart from the first semiconductor die, and at least one pair of differential channels connected to the first semiconductor die and the second semiconductor die, wherein the at least one pair of differential channels include at least one first differential channel and at least one second differential channel, each of which transmits a signal with a different phase, the at least one first differential channel includes a first capacitor, the at least one second differential channel includes a second capacitor, and each of the first capacitor and the second capacitor includes a first pad or bump connected to the first semiconductor die and a second pad or bump connected to the second semiconductor die.

According to another aspect of the present invention, the first capacitor and the second capacitor may be disposed in the package substrate.

According to still another aspect of the present invention, the semiconductor package may further include a passivation layer disposed on the first capacitor and the second capacitor.

According to yet another aspect of the present invention, the first pad or bump and the second pad or bump may be disposed on each of the first capacitor and the second capacitor, and the first pad or bump may be directly connected to a bump or pad disposed below the first semiconductor die, or the second pad or bump may be directly connected to a bump or pad disposed below the second semiconductor die.

According to yet another aspect of the present invention, the semiconductor package may further include an interposer disposed between the first and second semiconductor dies and the package substrate, wherein the first capacitor and the second capacitor may be disposed in the interposer.

According to yet another aspect of the present invention, the first capacitor and the second capacitor may be embedded in the interposer, and the interposer may include at least one of a first via formed to pass through between a bump or pad disposed below the first semiconductor die and the first pad, and a second via formed to pass through between a bump or pad disposed below the second semiconductor die and the second pad.

According to yet another aspect of the present invention, the first differential channel may further include at least one third capacitor connected in parallel with the first capacitor, and the second differential channel may further include at least one fourth capacitor connected in parallel with the second capacitor.

According to yet another aspect of the present invention, the semiconductor package may further include a plurality of switches each disposed between each of the first capacitor, the second capacitor, the third capacitor, and the fourth capacitor and the first semiconductor die or between each of the first capacitor, the second capacitor, the third capacitor, and the fourth capacitor and the second semiconductor die, wherein the first capacitor and the second capacitor may have the same capacitance, the third capacitor and the fourth capacitor may have the same capacitance, and the first capacitor and the third capacitor may have different capacitances.

According to yet another aspect of the present invention, a plurality of electrical paths may be disposed between the first semiconductor die and the second semiconductor die, and at least one of the plurality of electrical paths may include the at least one pair of differential channels.

According to yet another aspect of the present invention, the semiconductor package may further include a capacitor chip in which a plurality of capacitors are disposed on a single die, wherein the first capacitor and the second capacitor may be disposed in the capacitor chip.

According to yet another aspect of the present invention, at least one of the plurality of electrical paths may include a conductive wiring, and the conductive wiring may direct current (DC)-couple the first semiconductor die and the second semiconductor die.

According to yet another aspect of the present invention, the at least one pair of differential channels may be disposed as a plurality of pairs of differential channels, and among the plurality of pairs of differential channels, at least two pairs of differential channels may each include capacitors with different capacitances.

According to yet another aspect of the present invention, the first semiconductor die and the second semiconductor die may selectively transmit and receive an alternating current (AC) signal through an optimal path among the plurality of pairs of differential channels, and the optimal path may be determined by a frequency of the AC signal and the capacitances.

According to yet another aspect of the present invention, the first semiconductor die and the second semiconductor die may include a serializer and a deserializer, respectively.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a top view of a semiconductor package according to one embodiment of the present disclosure;

FIG. 2 is a cross-sectional view of the semiconductor package of FIG. 1, taken along line II-II′;

FIG. 3 is a cross-sectional view of another embodiment of the semiconductor package of FIG. 1, taken along line II-II′;

FIG. 4 is a cross-sectional view of still another embodiment of the semiconductor package of FIG. 1, taken along line II-II′;

FIG. 5 is a top view of a semiconductor package, in which each of differential channels includes a plurality of capacitors connected in parallel, according to another embodiment of the present disclosure;

FIG. 6 is a top view of a semiconductor package, in which each of differential channels includes capacitors connected in parallel and having different capacitances, according to still another embodiment of the present disclosure;

FIG. 7 is a top view of a semiconductor package including a capacitor chip, in which a plurality of capacitors are disposed, according to yet another embodiment of the present disclosure;

FIG. 8 is a top view of a semiconductor package including an alternating current (AC) coupling differential channel and a direct current (DC) coupling communication channel according to yet another embodiment of the present disclosure; and

FIG. 9 is a top view of a semiconductor package, in which each of different pairs of differential channels includes capacitors having different capacitances, according to yet another embodiment of the present disclosure.

### DETAILED DESCRIPTION OF EXEMPLARY EMBODIMENTS

Advantages and features of the present invention and implementation methods thereof will be clarified through the following embodiments described with reference to the accompanying drawings. However, the present invention is not limited to the embodiments described below and may be embodied with a variety of different modifications. The embodiments are merely provided to allow those skilled in the art to completely understand the scope of the present invention, and the present invention is defined only by the scope of the claims.

The figures, dimensions, ratios, angles, numbers, and the like disclosed in the drawings for describing the embodiments of the present invention are merely illustrative and are not limited to matters shown in the present invention. Further, in describing the present invention, detailed descriptions of well-known technologies will be omitted when it is determined that they may unnecessarily obscure the gist of the present invention. Terms such as “including,” “having,” and “composed of” used herein are intended to allow other elements to be added unless the terms are used with the term “only.” Any references to the singular may include the plural unless expressly stated otherwise.

Components are interpreted to include an ordinary error range even if not expressly stated.

Although the terms “first,” “second,” and the like may be used herein to describe various components, the components are not limited by the terms. These terms are used only to distinguish one component from another component. Therefore, a first component described below may be a second component within the technological scope of the present invention.

Unless otherwise indicated herein, throughout the specification, like reference numerals refer to like elements.

Features of various embodiments of the present invention may be partially or overall coupled to or combined with each other, and may be variously inter-operated with each other and driven technically as those skilled in the art can sufficiently understand. The embodiments of the present invention may be implemented independently from each other, or may be implemented together in co-dependent relationship.

The present invention will be described in detail with reference to the accompanying drawings.

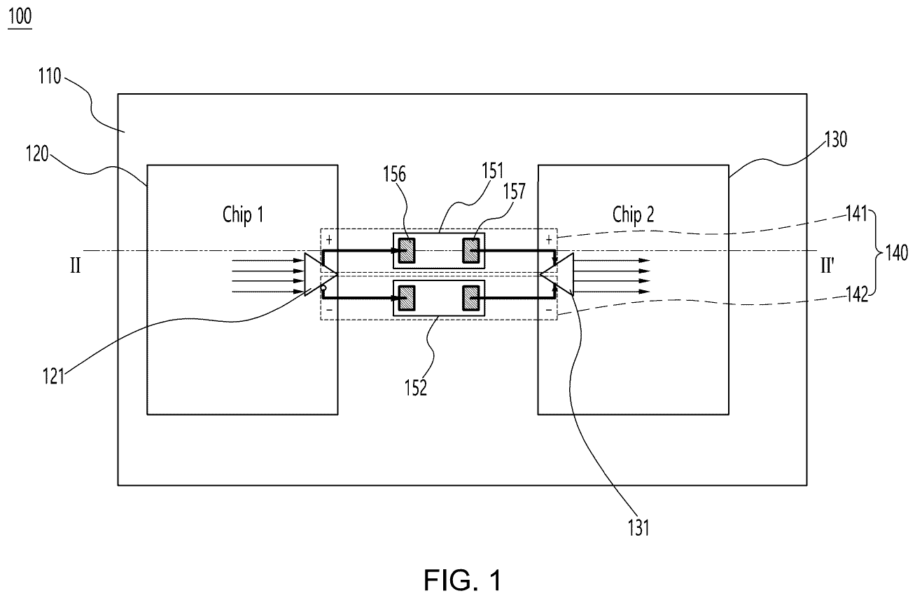

FIG. 1 is a top view of a semiconductor package according to one embodiment of the present disclosure.

Referring to FIG. 1, a semiconductor package 100 includes a package substrate 110, a first semiconductor die 120, a second semiconductor die 130, a pair of differential channels 140, and capacitors 151 and 152.

The semiconductor package 100 may be a device that protects the semiconductor dies and connects the semiconductor dies to an external circuit. Specifically, the semiconductor package 100 may be a device that integrates heterogeneous semiconductor dies into a single package. For example, the semiconductor package 100 may be a system-in-package (SiP).

The package substrate 110 is a substrate for a semiconductor package. Specifically, the package substrate 110 may connect at least one semiconductor die disposed on the package substrate 110 to external devices, or other chips or components. More specifically, the package substrate 110 may connect heterogeneous components disposed on the package substrate 110 to each other through bridge wirings, or connect the heterogeneous components to external devices through redistribution wirings.

The package substrate 110 may include a printed circuit board (PCB), an organic substrate, a ceramic substrate, a glass substrate, a silicon substrate, or a tape wiring substrate. For example, the package substrate 110 may be any one of a one-sided PCB, a double-sided PCB, and a multi-layer PCB.

The first semiconductor die 120 and the second semiconductor die 130 may be various electronic components, chips, or modules. For example, the first semiconductor die 120 and the second semiconductor die 130 may each include at least one of a central processing unit (CPU), a graphics processing unit (GPU), a neural processing unit (NPU), a memory, a communication module, and a radio frequency (RF) module. In some cases, the first semiconductor die 120 and the second semiconductor die 130 may be different electronic components. Specifically, the first semiconductor die 120 and the second semiconductor die 130 may be heterogeneous semiconductor dies fabricated through different manufacturing processes. Preferably, the first semiconductor die 120 and the second semiconductor die 130 may be chips, dies, or modules fabricated by microfabrication processes of different sizes. For example, the first semiconductor die 120 may be a semiconductor chip fabricated using a 14 nm process, and the second semiconductor die 130 may be a semiconductor chip fabricated using a 40 nm process. Accordingly, the semiconductor package 100 includes the first semiconductor die 120 and the second semiconductor die 130, which are heterogeneous, so that each of the semiconductor dies may be efficiently disposed for specialized tasks. In addition, chips or modules fabricated using different processes or in different sizes may be disposed on one package substrate 110, which may enhance the integration density of chips disposed in the package substrate 110 and also improve process efficiency and yield.

Referring to FIG. 1, the first semiconductor die 120 and the second semiconductor die 130 may include at least one serializer 121 and at least one deserializer 131. Accordingly, the first semiconductor die 120 and the second semiconductor die 130 may perform chip-to-chip communication through the serializer 121 and the deserializer 131, respectively.

The serializer 121 may transmit the same data signal with different phases. Specifically, the serializer 121 may transmit the same data signal with different phases through a first differential channel 141 and a second differential channel 142, respectively. For example, the serializer 121 may include an inverter on a data transmission path to the second differential channel 142. Accordingly, the serializer 121 can transmit signals with 180-degree opposite phases through the first differential channel 141 and the second differential channel 142.

As such, through the serializer 121 and the deserializer 131, the first semiconductor die 120 and the second semiconductor die 130 perform chip-to-chip communication in a serial manner rather than a parallel manner, thereby simplifying chip-to-chip communication lines. As a result, in the semiconductor package 100, the complexity of connections between components can be reduced. Furthermore, by configuring the chip-to-chip communication lines as a pair of differential channels, resistance to noise in serial chip-to-chip communication may be increased.

Referring to FIG. 1, the first semiconductor die 120 and the second semiconductor die 130 may be disposed on the package substrate 110. Specifically, the first semiconductor die 120 and the second semiconductor die 130 may be disposed on the package substrate 110 to be spaced apart from each other. According to various embodiments of the present invention, the first semiconductor die 120 and the second semiconductor die 130 may be disposed adjacent to each other. In some cases, the first semiconductor die 120 and the second semiconductor die 130 may be disposed in contact with each other. Thus, in the semiconductor package 100, miniaturization and integration density may be improved, and functions between the semiconductor dies 120 and 130 may be more efficiently integrated.

Referring to FIG. 1, at least one pair of differential channels 140 for transmitting differential signals may be disposed between the first semiconductor die 120 and the second semiconductor die 130. The at least one pair of differential channels 140 may include a first differential channel 141 and a second differential channel 142, which respectively transmit signals with different phases. For example, the first differential channel 141 and the second differential channel 142 may transmit the same data signal with 180-degree opposite phases. Thus, the first semiconductor die 120 and the second semiconductor die 130 may improve electromagnetic interference (EMI) performance of chip-to-chip communication by performing the chip-to-chip communication through the differential channels. Furthermore, the semiconductor package 100 may enhance resistance to cross talk and noise in serial chip-to-chip communication and improve signal integrity by configuring the chip-to-chip communication lines as a pair of differential channels.

The semiconductor package 100 includes at least two capacitors 151 and 152. Specifically, the semiconductor package 100 may include capacitors respectively disposed on the first differential channel 141 and the second differential channel 142, which are at least one pair of differential channels.

A first capacitor 151 and a second capacitor 152 may be various types of capacitors. For example, each of the first capacitor 151 and the second capacitor 152 may be a multi-layer ceramic capacitor (MLCC), a trench capacitor, a silicon capacitor, an embedded capacitor, and a thin-film capacitor. Preferably, each of the first capacitor 151 and the second capacitor 152 may be a deep trench capacitor (DTC). Accordingly, the semiconductor package 100 can include a deep trench capacitor, which is advantageous for miniaturization and capable of securing capacitance in a vertical direction, thereby efficiently providing capacitances to semiconductor dies within a limited space.

The first capacitor 151 and the second capacitor 152 may be identical capacitors. Specifically, the first capacitor 151 and the second capacitor 152 may have the same type, size, and capacitance.

Referring to FIG. 1, the capacitors 151 and 152 may be respectively disposed in the at least one pair of differential channels 140. Specifically, the first capacitor 151 may be alternating current (AC)-coupled to the first differential channel 141, and the second capacitor 152 may be AC-coupled to the second differential channel 142. Accordingly, the first semiconductor die 120 and the second semiconductor die 130 may be AC-coupled through the first capacitor 151 and the second capacitor 152. For example, as shown in FIG. 1, a first pad or bump 156 of each of the first capacitor 151 and the second capacitor 152 may be connected to the first semiconductor die 120, and a second pad or bump 157 of each of the first capacitor 151 and the second capacitor 152 may be connected to the second semiconductor die 130. Accordingly, the first capacitor 151 and the second capacitor 152 can reduce signal distortion and improve the integrity of data transmission by removing a direct current (DC) offset and suppressing crosstalk or noise in the differential channels between the first semiconductor die 120 and the second semiconductor die 130. In addition, the first capacitor 151 and the second capacitor 152 may ensure the symmetry and stability of differential signals by reducing electrical imbalance in the first differential channel 141 and the second differential channel 142.

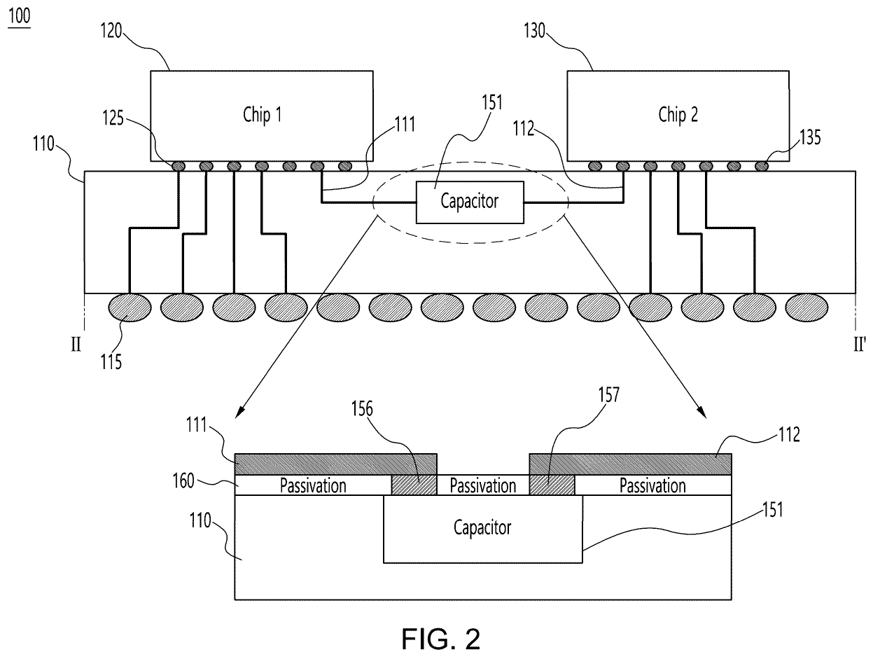

Referring to FIG. 1, the first capacitor 151 and the second capacitor 152 may be disposed between the first semiconductor die 120 and the second semiconductor die 130. Specifically, the first capacitor 151 and the second capacitor 152 may be disposed on the package substrate 110 between the first semiconductor die 120 and the second semiconductor die 130. In some cases, the first capacitor 151 and the second capacitor 152 may be disposed in the package substrate 110, or may be disposed in an interposer (not shown) disposed between the package substrate 110 and the first and second semiconductor dies 120 and 130. For example, the first capacitor 151 and the second capacitor 152 may be embedded in the package substrate 110 and disposed below the first semiconductor die 120 or the second semiconductor die 130. The detailed arrangement relationship between the first and second capacitors 151 and 152 and the first and second semiconductor dies 120 and 130 will be described later with reference to FIGS. 2 to 4.

FIG. 2 is a cross-sectional view of the semiconductor package of FIG. 1, taken along line II-II′.

Referring to FIG. 2, the semiconductor package 100 may further include first connection bumps 115, second connection bumps or pads 125, third connection bumps or pads 135, and a passivation layer 160.

The first connection bump 115, the second connection bump or pad 125, and the third connection bump or pad 135 may include various types of bumps and pads. For example, each of the first connection bump 115, the second connection bump or pad 125, and the third connection bump or pad 135 may include any one of a solder ball, a flip-chip bump, a Cu bump, an Au bump, and a polymer bump. Furthermore, each of the second connection bump or pad 125 and the third connection bump or pad 135 may include one of a Cu pad, a W pad, a Ni/Au pad, and an Al pad.

The first connection bump 115 may be disposed below the package substrate 110. Specifically, the first connection bump 115 may be disposed on a lower surface of the pad disposed on a lower surface of the package substrate 110.

The first connection bumps 115 may connect the package substrate 110 to an external device. For example, the first connection bumps 115 may connect the package substrate 110 to a PCB disposed below the package substrate 110.

The second connection bumps or pads 125 may be disposed below the first semiconductor die 120. Specifically, the second connection bumps or pads 125 may be disposed between the first semiconductor die 120 and the package substrate 110. More specifically, the second connection bump or pad 125 may be disposed between the pad disposed on a lower surface of the first semiconductor die 120 and the pad disposed on an upper surface of the package substrate 110.

The second connection bump or pad 125 may connect the first semiconductor die 120 and the package substrate 110. That is, the first semiconductor die 120 may be connected to an external device through the second connection bumps or pads 125 and the redistribution wiring of the package substrate 110.

The third connection bumps or pads 135 may be disposed below the second semiconductor die 130. Specifically, the third connection bumps or pads 135 may be disposed between the second semiconductor die 130 and the package substrate 110. More specifically, the third connection bump or pad 135 may be disposed between the pad disposed on a lower surface of the second semiconductor die 130 and the pad disposed on the upper surface of the package substrate 110.

The third connection bumps or pads 135 may connect the second semiconductor die 130 and the package substrate 110. That is, the second semiconductor die 130 may be connected to an external device through the third connection bumps or pads 135 and the redistribution wiring of the package substrate 110.

Referring to FIG. 2, the first capacitor 151 includes the first pad or bump 156 and the second pad or bump 157. The first pad or bump 156 may be connected to one electrode of the first capacitor 151, and the second pad or bump 157 may be connected to the other electrode of the first capacitor 151. As shown in FIG. 2, the first pad or bump 156 and the second pad or bump 157 may be disposed on an upper surface of the first capacitor 151. In some cases, the first pad or bump 156 and the second pad or bump 157 may be disposed on a side or lower surface of the first capacitor 151.

The first capacitor 151 and the second capacitor (not shown in FIG. 2) may be disposed in the package substrate 110. Specifically, the first capacitor 151 and the second capacitor may be disposed in grooves formed in the upper surface of the package substrate 110. In some cases, the first capacitor 151 and the second capacitor may be embedded in the package substrate 110.

The first capacitor 151 and the second capacitor may be connected to the first semiconductor die 120 and the second semiconductor die 130 respectively through a first bridge wiring 111 and a second bridge wiring 112. Specifically, as shown in FIG. 2, the first pad or bump 156 of the first capacitor 151 may be connected to the first semiconductor die 120 through the first bridge wiring 111, and the second pad or bump 157 of the first capacitor 151 may be connected to the second semiconductor die 130 through the second bridge wiring 112.

Referring to FIG. 2, the first bridge wiring 111 and the second bridge wiring 112 may be disposed on the passivation layer 160. In some cases, the first bridge wiring 111 and the second bridge wiring 112 may be disposed between a plurality of passivation layers 160 and may also be disposed on the upper surface of the package substrate 110. When the first capacitor 151 is embedded in the package substrate 110, the first bridge wiring 111 and the second bridge wiring 112 may also be disposed in the package substrate 110.

The passivation layer 160 may be disposed on the package substrate 110. Specifically, as shown in FIG. 2, the passivation layer 160 may be disposed on the upper surface of the package substrate 110 and the upper surface of the first capacitor 151.

The passivation layer 160 may include low-dielectric constant and low-loss tangent materials. Specifically, the passivation layer 160 may include various low-dielectric constant materials depending on the package substrate 110. For example, when the package substrate 110 is a silicon substrate, the passivation layer 160 may include at least one of SiO₂, Si₃N₄, SiCN, and SiCOH. When the package substrate 110 is an organic substrate, the passivation layer 160 may include at least one polymer-based low-dielectric constant material such as benzocyclobutene (BCB), polyimide, or cyclic olefin copolymer (COC). When the package substrate 110 is a glass substrate, the passivation layer 160 may include at least one of a polymer material and a porous material that are stable and have a coefficient of thermal expansion similar to that of the glass substrate. Accordingly, the passivation layer 160 may reduce transmission loss in wirings in the package substrate 110 by including low-dielectric constant and low-loss tangent materials depending on the package substrate 110.

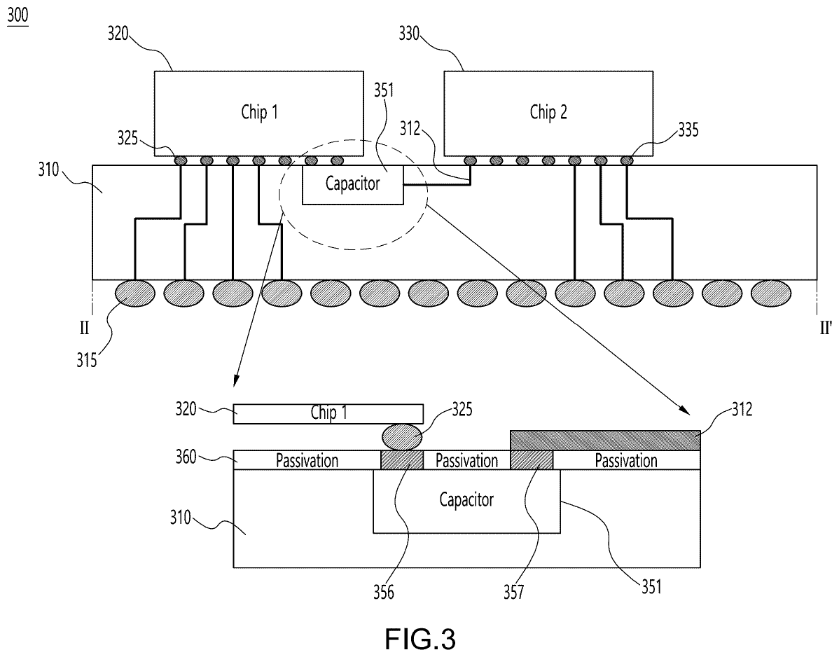

FIG. 3 is a cross-sectional view of another embodiment of the semiconductor package of FIG. 1, taken along line II-II′.

Referring to FIG. 3, a semiconductor package 300 according to the present embodiment may be configured such that at least a portion of a first capacitor 351 is disposed below a first semiconductor die 320 based on the configuration of the semiconductor package 100 of FIG. 1. Accordingly, redundant descriptions of configurations that are substantially identical to those of the semiconductor package 100 of FIGS. 1 and 2 will be omitted.

The first capacitor 351 and a second capacitor (not shown) may be disposed below the first semiconductor die 320 or a second semiconductor die 330. Specifically, at least a portion of each of the first capacitor 351 and the second capacitor may be disposed to overlap the first semiconductor die 320 or the second semiconductor die 330 at a position below the first semiconductor die 320 or the second semiconductor die 330. For example, as shown in FIG. 3, the first capacitor 351 may be disposed in a partial region below the first semiconductor die 320. In some cases, the first capacitor 351 may be disposed in a partial region below the second semiconductor die 330. When the first semiconductor die 320 and the second semiconductor die 330 are disposed in close contact with each other, the first capacitor 351 may also be disposed in a partial region below each of the first semiconductor die 320 and the second semiconductor die 330.

The first capacitor 351 and the second capacitor (not shown) may be directly connected the first semiconductor die 320. Specifically, as shown in FIG. 3, a first pad or bump 356 of the first capacitor 351 may be directly connected to a second connection bump or pad 325 disposed below the first semiconductor die 320. In some cases, a second pad or bump 357 of the first capacitor 351 may be directly connected to a third connection bump or pad 335 disposed below the second semiconductor die 330. Accordingly, the semiconductor package 300 may not include at least one of a first bridge wiring (not shown) and a second bridge wiring 312. The second capacitor (not shown) may have substantially the same arrangement and connection relationship as the first capacitor 351.

The semiconductor package 300 according to the present embodiment may include the first capacitor 351 and the second capacitor disposed below the first semiconductor die 320 or the second semiconductor die 330, which allows the first semiconductor die 320 and the second semiconductor die 330 to be disposed in close contact with each other. Thus, the integration density of the semiconductor package 300 may be improved. Furthermore, the semiconductor package 300 may reduce equivalent series inductance (ESL) and equivalent series resistance (ESR) by including a reduced number of bridge wirings.

In the semiconductor package 300 according to the present embodiment, the first bridge wiring (not shown) and contact holes may be omitted by including the first capacitor 351 and the second capacitor that are directly connected below the first semiconductor die 320 or the second semiconductor die 330. Accordingly, in the semiconductor package 300, impedance discontinuities can be reduced and signal integrity can be improved by omitting a contact portion between the second connection bump or pad 325 and the first bridge wiring, a contact portion between vertical and horizontal wirings of the first bridge wiring, and a contact portion between the first bridge wiring and the first pad or bump 356.

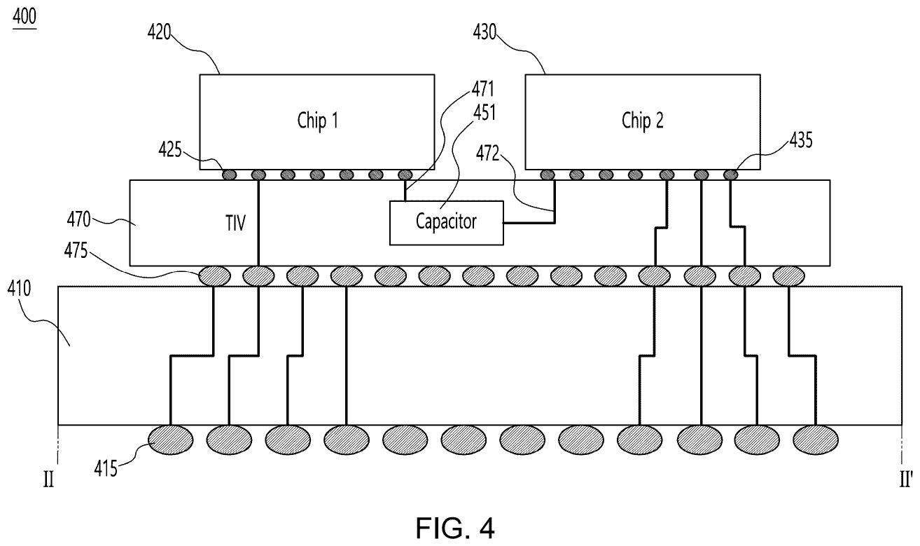

FIG. 4 is a cross-sectional view of still another embodiment of the semiconductor package of FIG. 1, taken along line II-II′.

Referring to FIG. 4, a semiconductor package 400 according to the present embodiment may further include an interposer 470 and may be configured such that a first capacitor 451 is disposed in the interposer 470 based on the configuration of the semiconductor package 100 of FIG. 1. Accordingly, redundant descriptions of configurations that are substantially identical to those of the semiconductor package 100 of FIG. 1 will be omitted.

The interposer 470 may include a semiconductor material. For example, the interposer 470 may include semiconductor elements such as silicon and germanium, or compound semiconductors such as SiC, GaAs, InAs, and InP. Preferably, the interposer 470 may be a silicon interposer. According to various embodiments of the present invention, the interposer 470 may include an organic material. For example, the interposer 470 may be an organic interposer that includes materials such as polyimide, bismaleimide triazine (BT) resin, and Ajinomoto build-up film (ABF).

The interposer 470 may be disposed below a first semiconductor die 420 and a second semiconductor die 430. Specifically, as shown in FIG. 4, the interposer 470 may be disposed between the first and second semiconductor dies 420 and 430 and a package substrate 410.

The interposer 470 may connect the first and second semiconductor dies 420 and 430 to the package substrate 410. Specifically, the first and second semiconductor dies 420 and 430 may be connected to the package substrate 410 through through-interposer vias (TIVs) disposed in the interposer 470 and fourth connection bumps or pads 475 disposed below the interposer 470. In some cases, the interposer 470 may connect the first and second semiconductor dies 420 and 430 to the package substrate 410 through the TIVs or redistribution wirings.

The interposer 470 may connect the first semiconductor die 420 and the second semiconductor die 430. Specifically, the first semiconductor die 420 and the second semiconductor die 430 may be connected to each other through bridge wirings 471 and 472 disposed in the interposer 470. Preferably, as shown in FIG. 4, the first semiconductor die 420 and the second semiconductor die 430 may be connected to each other through the first capacitor 451 and the bridge wirings 471 and 472 disposed in the interposer 470.

The first capacitor 451 may be disposed in the interposer 470. Specifically, the first capacitor 451 may be embedded in the interposer 470. In some cases, the first capacitor 451 may be disposed in a groove formed in an upper surface of the interposer 470.

The arrangement relationship between the first capacitor 451 and the first and second semiconductor dies 420 and 430 may be substantially the same as the arrangement relationship between the first capacitor 351 and the first and second semiconductor dies 320 and 330 of FIG. 3. That is, the first capacitor 451 may be disposed below the first semiconductor die 420 or below the second semiconductor die 430. The second capacitor (not shown) may have substantially the same arrangement and connection relationship as the first capacitor 451. In this case, the first capacitor 451 may be disposed to overlap the first semiconductor die 420 or the second semiconductor die 430 at a position therebelow.

Referring to FIG. 4, the first capacitor 451 may be connected to the first semiconductor die 420 through a first bridge wiring 471 and connected to the second semiconductor die 430 through a second bridge wiring 472. When the first capacitor 451 is disposed below the first semiconductor die 420, the first bridge wiring 471 may be a vertical via. In some cases, only the second bridge wiring 472 may be a vertical via, or both the first bridge wiring 471 and the second bridge wiring 472 may be vertical vias.

When the first bridge wiring 471 and the second bridge wiring 472 are vertical vias, the first bridge wiring 471 and the second bridge wiring 472 may be formed by the same process as the TIVs of the interposer 470. Accordingly, in the manufacturing process of the interposer 470, additional wiring processes for forming horizontal wirings and bridge wirings may be omitted, and wiring complexity within the interposer 470 may be reduced.

The semiconductor package 400 according to the present embodiment may include the first capacitor 451 connected to the semiconductor dies 420 and 430 through the vertical via-type bridge wirings 471 and 472 in the interposer 470, thereby allowing the bridge wirings 471 and 472 to be formed using the same process as the TIVs of the interposer 470. Accordingly, since the TIVs and the bridge wirings 471 and 472 are simultaneously formed in a single process without additional wiring processes, the manufacturing process can be simplified, thereby reducing time and costs. In addition, the interposer 470 can reduce wiring complexity and significantly increase wiring density by connecting the embedded first capacitor 451 using only the vertical vias.

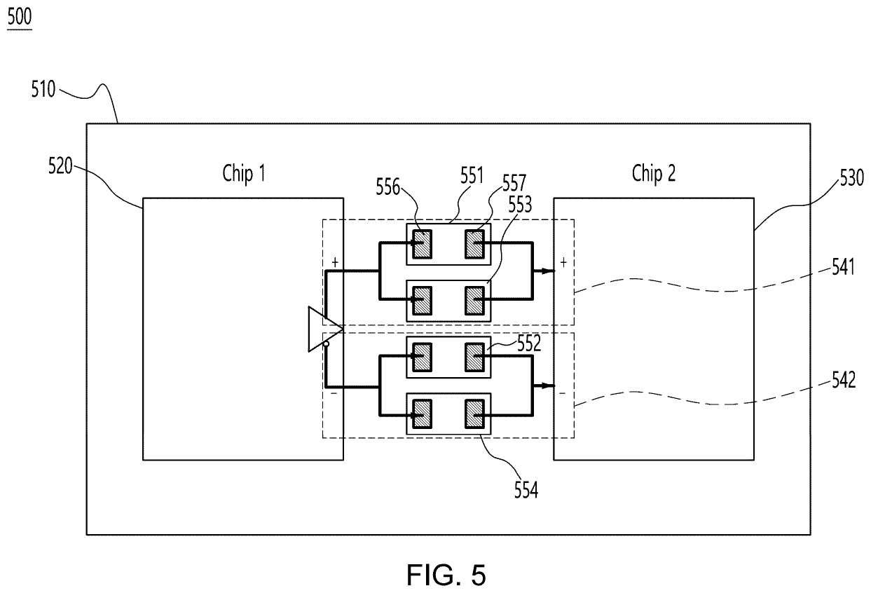

FIG. 5 is a top view of a semiconductor package, in which each of differential channels includes a plurality of capacitors connected in parallel, according to another embodiment of the present disclosure.

Referring to FIG. 5, a semiconductor package 500 according to the present embodiment may further include at least two capacitor 553 and 554 and may be configured such that a plurality of capacitors 551 and 553 are connected in parallel with each other based on the configuration of the semiconductor package 100 of FIG. 1. Accordingly, redundant descriptions of configurations that are substantially identical to those of the semiconductor package 100 of FIG. 1 will be omitted.

Each of the plurality of capacitors 551, 552, 553, and 554 may be substantially the same as the first capacitor 151 of FIG. 1. Specifically, each of the plurality of capacitors 551, 552, 553, and 554 may have the same type, size, and capacitance as the first capacitor 151 of FIG. 1.

The plurality of capacitors 551, 552, 553, and 554 may be disposed in a package substrate 510. According to various embodiments of the present invention, the plurality of capacitors 551, 552, 553, and 554 may be disposed in an interposer (not shown) disposed between first and second semiconductor dies 520 and 530 and the package substrate 510.

At least two of the plurality of capacitors 551, 552, 553, and 554 may be connected in parallel. Specifically, the plurality of capacitors 551, 552, 553, and 554 may be divided into two units and connected in parallel. For example, as shown in FIG. 5, a first capacitor 551 and a third capacitor 553 may be connected in parallel, and a second capacitor 552 and a fourth capacitor 554 may be connected in parallel.

The capacitors 551 and 553 connected in parallel may be disposed on an electrical path between the first semiconductor die 520 and the second semiconductor die 530. Specifically, the first capacitor 551 and the third capacitor 553 connected in parallel may be disposed on a first differential channel 541, and the second capacitor 552 and the fourth capacitor 554 connected in parallel may be disposed on a second differential channel 542. For example, the first capacitor 551 and the third capacitor 553 connected in parallel are disposed on the first differential channel 541 while AC coupling the first semiconductor die 520 and the second semiconductor die 530. Similarly, the second capacitor 552 and the fourth capacitor 554 connected in parallel are disposed on the second differential channel 542 while AC coupling the first semiconductor die 520 and the second semiconductor die 530.

The number of the plurality of capacitors 551 and 553 connected in parallel may be determined based on the frequency of a chip-to-chip communication signal between the first semiconductor die 520 and the second semiconductor die 530. Specifically, the number of the plurality of capacitors 551 and 553 connected in parallel in one differential channel may be determined such that an optimal equivalent capacitance is achieved according to the frequency of the chip-to-chip communication signal between the first semiconductor die 520 and the second semiconductor die 530.

According to various embodiments of the present invention, each of a plurality of switches (not shown) may be disposed between each of the plurality of capacitors 551, 552, 553, and 554 and the first semiconductor die 520 or the second semiconductor die 530. For example, each switch may be disposed between a first pad or bump 556 of each of the plurality of capacitors 551, 552, 553, and 554 and the first semiconductor die 520. The first semiconductor die 520 and the second semiconductor die 530 may control ON/OFF of each of the plurality of switches. Accordingly, the first semiconductor die 520 and the second semiconductor die 530 can adjust an equivalent capacitance of each of the differential channels 541 and 542 in real time by controlling the switches in real time based on the frequency of a transmission signal. Accordingly, the first semiconductor die 520 and the second semiconductor die 530 can minimize signal distortion according to a frequency band of the chip-to-chip communication signal and maintain uniform signal quality over a wide bandwidth by adjusting the equivalent capacitance of the chip-to-chip communication line in real time according to the frequency of the transmission signal.

In the semiconductor package 500 according to the present embodiment, the equivalent capacitance may be precisely implemented according to the frequency of the chip-to-chip communication signal by including a plurality of AC coupling capacitors connected in parallel. In addition, even when errors occur in the capacitances of the capacitors due to manufacturing tolerances, a target capacitance can be more closely approximated through parallel combination.

Further, in the semiconductor package 500 according to the present embodiment, the equivalent capacitance of each differential channel may be adjusted in real time by including the first semiconductor die 520 and the second semiconductor die 530, which control the connection of each of the capacitors connected in parallel using switches. Accordingly, the semiconductor package 500 can minimize signal distortion according to the frequency band of the chip-to-chip communication signal and maintain uniform signal quality over a wide bandwidth.

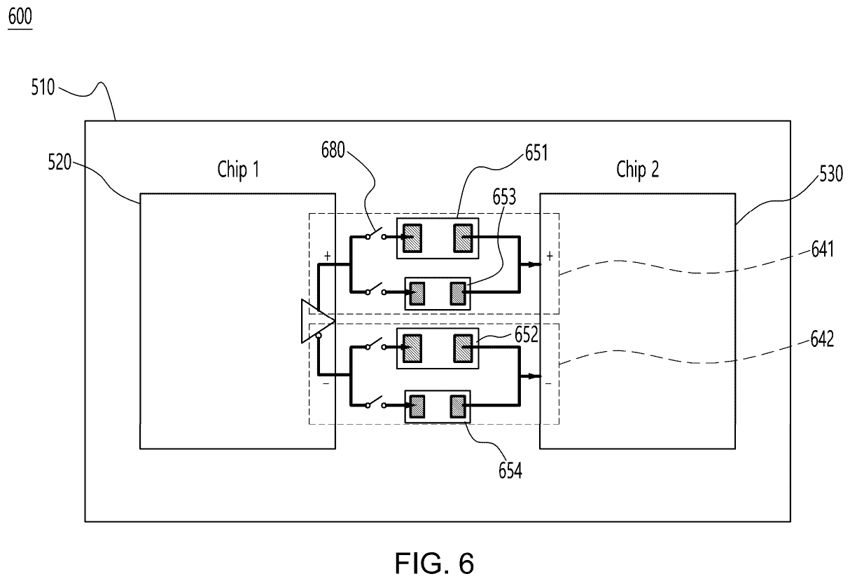

FIG. 6 is a top view of a semiconductor package, in which each of differential channels includes capacitors connected in parallel and having different capacitances, according to still another embodiment of the present disclosure.

Referring to FIG. 6, a semiconductor package 600 according to the present embodiment may include a plurality of capacitors 651 and 653 connected in parallel and having different capacitances and may further include switches 680 based on the configuration of the semiconductor package 500 of FIG. 5. Accordingly, redundant descriptions of configurations that are substantially identical to those of the semiconductor package 500 of FIG. 5 will be omitted.

The plurality of capacitors 651 and 653 connected in parallel may have different capacitances. For example, as shown in FIG. 6, a first capacitor 651 and a third capacitor 653 are connected in parallel with each other, and the first capacitor 651 may have a larger capacitance than the third capacitor 653. Further, a second capacitor 652 and a fourth capacitor 654 are connected in parallel with each other, and the second capacitor 652 may have a larger capacitance than the fourth capacitor 654.

An equivalent capacitance of each differential channel may be the same. Specifically, the equivalent capacitance of a first differential channel 641 and the equivalent capacitance of a second differential channel may be the same. For example, the capacitance of the first capacitor 651 and the capacitance of the second capacitor 652 may be the same, and the capacitance of the third capacitor 653 and the capacitance of the fourth capacitor 654 may be the same. Accordingly, electrical imbalance between the differential channels 641 and 642 can be prevented, and the symmetry and stability of differential signals can be ensured.

A plurality of capacitors 651, 652, 653, and 654 may be disposed in the package substrate 510. According to various embodiments of the present invention, the plurality of capacitors 651, 652, 653, and 654 may be disposed in the interposer (not shown) disposed between first and second semiconductor dies 520 and 530 and the package substrate 510.

Referring to FIG. 6, each of a plurality of switches 680 may be disposed between each of the plurality of capacitors 651, 652, 653, and 654 and the first semiconductor die 520 or the second semiconductor die 530. The first semiconductor die 520 and the second semiconductor die 530 may control ON/OFF of each of the plurality of switches 680. Accordingly, the first semiconductor die 520 and the second semiconductor die 530 can control the switches 680 in real time based on the frequency of the transmission signal, thereby adjusting the equivalent capacitance of each of the differential channels 641 and 642 in real time. Accordingly, the first semiconductor die 520 and the second semiconductor die 530 can minimize signal distortion according to a frequency band of the chip-to-chip communication signal and maintain uniform signal quality over a wide bandwidth by adjusting the equivalent capacitance of the chip-to-chip communication line in real time according to the frequency of the transmission signal.

In the semiconductor package 600 according to the present embodiment, the equivalent capacitance may be more finely and accurately adjusted by including AC coupling capacitors that are connected in parallel and have different capacitances.

Further, in the semiconductor package 600 according to the present embodiment, the equivalent capacitance of each differential channel may be more finely adjusted in real time by including the first semiconductor die 520 and the second semiconductor die 530, which control the connection of each of the capacitors connected in parallel and having different capacitances by using switches. Accordingly, the semiconductor package 600 can minimize signal distortion according to the frequency band of the chip-to-chip communication signal and maintain uniform signal quality over a wide bandwidth.

Further, in the semiconductor package 600 according to the present embodiment, each capacitor may operate with optimal signal transmission characteristics over various frequency bands by including AC coupling capacitors that are connected in parallel and have different capacitances. For example, in the semiconductor package 600, appropriate capacitor paths may be utilized across all frequency bands by including a high-capacitance capacitor for low-frequency signals, a mid-capacitance capacitor for mid-frequency signals, and a low-capacitance capacitor for high-frequency signals, thereby maintaining signal quality.

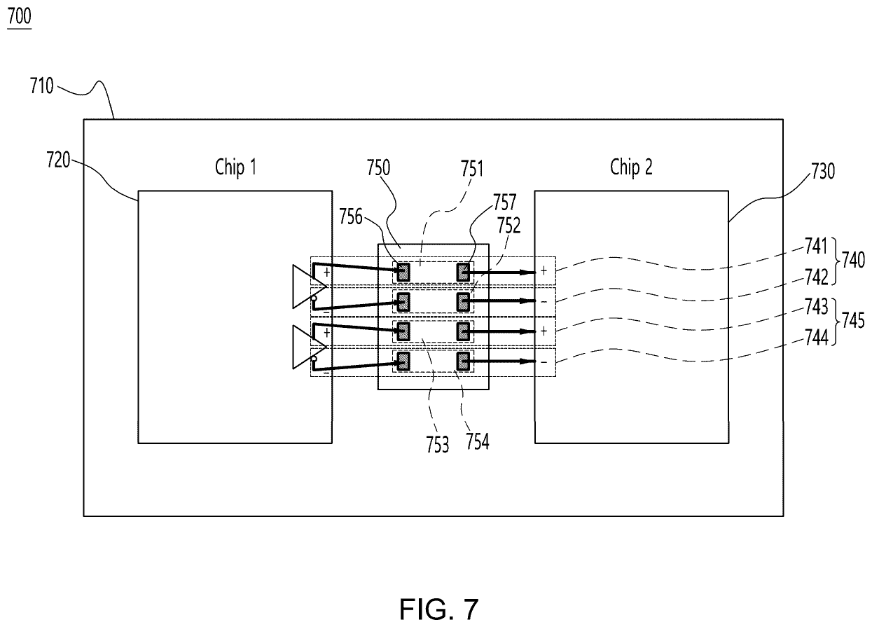

FIG. 7 is a top view of a semiconductor package including a capacitor chip, in which a plurality of capacitors are disposed, according to yet another embodiment of the present disclosure.

Referring to FIG. 7, a semiconductor package 700 according to the present embodiment may further include a capacitor chip 750 in which a plurality of capacitors are disposed and may be configured such that a plurality of pairs of differential channels are disposed based on the configuration of the semiconductor package 100 of FIG. 1.

The capacitor chip 750 may include a plurality of capacitors 751, 752, 753, and 754. Specifically, the capacitor chip 750 may include the plurality of capacitors 751, 752, 753, and 754 disposed on a single die.

The capacitor chip 750 may be disposed in a package substrate 710. Specifically, the capacitor chip 750 may be disposed in a groove formed in an upper surface of the package substrate 710, or may be embedded in the package substrate 710. According to various embodiments of the present invention, the capacitor chip 750 may be disposed in an interposer (not shown) disposed between first and second semiconductor dies 720 and 730 and the package substrate 710.

Each of the plurality of capacitors 751, 752, 753, and 754 may be substantially the same as the first capacitor 151 of FIG. 1. Specifically, each of the plurality of capacitors 751, 752, 753, and 754 may have the same type, size, and capacitance as the first capacitor 151 of FIG. 1.

The plurality of capacitors 751, 752, 753, and 754 may be disposed adjacent to each other in the capacitor chip 750. Specifically, the plurality of capacitors 751, 752, 753, and 754 may be disposed adjacent to each other in one direction in the capacitor chip 750. For example, as shown in FIG. 7, a first pad or bump 756 of each of the plurality of capacitors 751, 752, 753, and 754 may be disposed to face the first semiconductor die 720, and a second pad or bump 757 of each of the plurality of capacitors 751, 752, 753, and 754 may be disposed to face the second semiconductor die 730.

A plurality of electrical paths may be disposed between the first semiconductor die 720 and the second semiconductor die 730. Specifically, a plurality of pairs of differential channels 740 and 745 may be disposed between the first semiconductor die 720 and the second semiconductor die 730.

The plurality of capacitors 751, 752, 753, and 754 may be disposed on the plurality of electrical paths, respectively. Specifically, the capacitor may be disposed in each of the differential channels 741, 742, 743, and 744 of the plurality of pairs of differential channels 740 and 745. For example, a first capacitor 751 may be AC-coupled to a first differential channel 741 of a first pair of differential channels 740, a second capacitor 752 may be AC-coupled to a second differential channel 742 of the first pair of differential channels 740, a third capacitor 753 may be AC-coupled to a first differential channel 743 of a second pair of differential channels 745, and a fourth capacitor 754 may be AC-coupled to a second differential channel 744 of the second pair of differential channels 745.

According to various embodiments of the present invention, at least one switch (not shown) may be disposed on each of the plurality of electrical paths disposed between the first semiconductor die 720 and the second semiconductor die 730. Specifically, the switch may be disposed between each of the plurality of capacitors 751, 752, 753, and 754 and the first semiconductor die 720 or the second semiconductor die 730. For example, each switch may be disposed between the first pad or bump 756 of each of the plurality of capacitors 751, 752, 753, and 754 and the first semiconductor die 720.

In some cases, a plurality of switches may be disposed in the first semiconductor die 720 or the second semiconductor die 730. Specifically, the plurality of switches may be disposed in the first semiconductor die 720 or the second semiconductor die 730, along the respective electrical paths between the first semiconductor die 720 and the second semiconductor die 730.

The first semiconductor die 720 and the second semiconductor die 730 may control ON/OFF of each of the plurality of switches. Accordingly, the first semiconductor die 720 and the second semiconductor die 730 can select a chip-to-chip communication line with a capacitance optimized for the frequency of a transmission signal by controlling the switches in real time based on the frequency of the transmission signal. Accordingly, the first semiconductor die 720 and the second semiconductor die 730 can minimize signal distortion based on a frequency band of the chip-to-chip communication signal and maintain uniform signal quality over a wide bandwidth by switching the chip-to-chip communication line to an electrical path with an optimal capacitance in real time. In the semiconductor package 700 according to the present embodiment, the plurality of capacitors 751, 752, 753, and 754 may be integrated into one capacitor chip 750, thereby minimizing a spacing between the plurality of capacitors 751, 752, 753, and 754. Accordingly, in the semiconductor package 700, a larger number of capacitors can be integrated in the same area, thereby achieving higher capacitance within the same space and improving area efficiency of the package. In addition, by including the plurality of capacitors 751, 752, 753, and 754 in one capacitor chip 750 and connecting a different electrical path to each of the capacitors 751, 752, 753, and 754, a signal can be transmitted through various electrical paths selected according to the characteristics of the signal. In particular, when each of the capacitors 751, 752, 753, and 754 has a different capacitance, one capacitor chip 750 can provide various electrical paths alone, thereby enhancing the integration density of the semiconductor package 700.

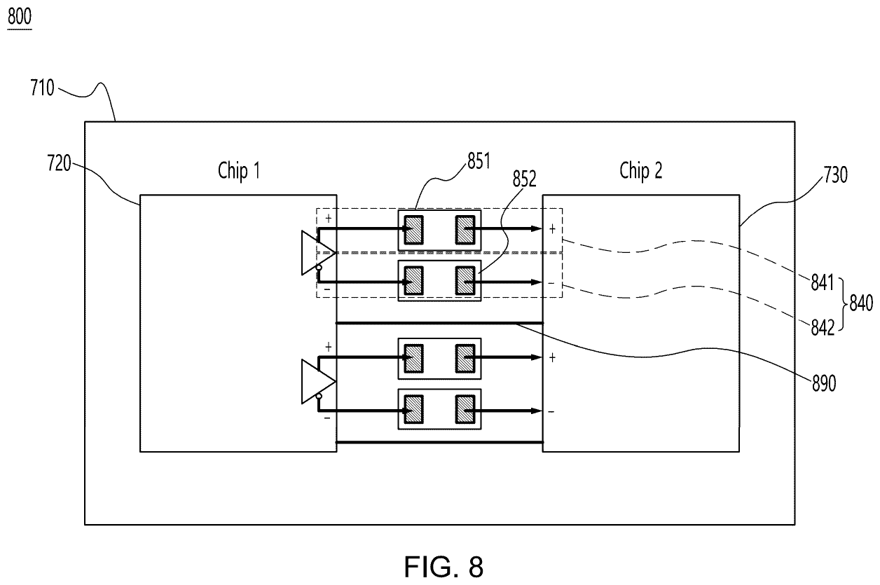

FIG. 8 is a top view of a semiconductor package including an AC coupling differential channel and a DC coupling communication channel according to yet another embodiment of the present disclosure.

Referring to FIG. 8, a semiconductor package 800 according to the present embodiment may further include a conductive wiring 890 and may be configured such that a plurality of chip-to-chip communication lines are disposed based on the configuration of the semiconductor package 100 of FIG. 1. Accordingly, redundant descriptions of configurations that are substantially identical to those of the semiconductor package 100 of FIG. 1 will be omitted.

Each of a first capacitor 851 and a second capacitor 852 may be substantially the same as the first capacitor 151 of FIG. 1. Specifically, the first capacitor 851 and the second capacitor 852 may have the same type, size, and capacitance as the first capacitor 151 of FIG. 1.

The first capacitor 851 and the second capacitor 852 may be disposed in the package substrate 710. According to various embodiments of the present invention, the first capacitor 851 and the second capacitor 852 may be disposed in the interposer (not shown) disposed between the first and second semiconductor dies 720 and 730 and the package substrate 710.

A plurality of electrical paths may be disposed between the first semiconductor die 720 and the second semiconductor die 730. Specifically, as shown in FIG. 8, between the first semiconductor die 720 and the second semiconductor die 730, at least one pair of differential channels 840, in which a first capacitor 851 and a second capacitor 852 are respectively disposed, may be disposed, and at least one chip-to-chip communication channel composed of a conductive wiring 890 may be disposed. That is, at least one first differential channel 841, in which the first capacitor 851 is AC-coupled, at least one second differential channel 842, in which the second capacitor 852 is AC-coupled, and at least one chip-to-chip communication channel, in which the conductive wiring 890 is DC-coupled, may be disposed between the first semiconductor die 720 and the second semiconductor die 730.

The conductive wiring 890 may be a bridge wiring disposed on the package substrate 710. Specifically, the conductive wiring 890 may be a metal wiring disposed on the package substrate 710. In some cases, the conductive wiring 890 may also be a metal wiring disposed in the package substrate 710. According to various embodiments of the present invention, the conductive wiring 890 may be disposed in the interposer (not shown) disposed between the first and second semiconductor dies 720 and 730 and the package substrate 710.

Referring to FIG. 8, the conductive wiring 890 may be a chip-to-chip communication channel composed of a single wiring. In some cases, a plurality of conductive wirings 890 may form a single chip-to-chip communication channel. For example, a pair of conductive wirings 890 may form a single chip-to-chip communication channel. According to various embodiments of the present invention, the pair of conductive wirings 890 may be a pair of differential channels. That is, the first semiconductor die 720 and the second semiconductor die 730 may transmit a DC differential signal or a low-frequency differential signal through the pair of conductive wirings 890. Accordingly, the semiconductor package 800 can achieve higher EMI immunity by suppressing common mode noise of DC transmission signals as well as AC signals. In addition, the semiconductor package 800 may ensure the integrity of both high-speed data signals and low-speed signals by individually optimizing the AC-coupled channel and the DC-coupled channel.

The first semiconductor die 720 and the second semiconductor die 730 may selectively use the pair of differential channels 840, in which the first capacitor 851 and the second capacitor 852 are disposed, or the communication channel composed of the conductive wiring 890. Specifically, the first semiconductor die 720 and the second semiconductor die 730 may select an optimal communication channel based on the type and frequency of a transmission signal and transmit the signal through the optimal communication channel. The optimal communication channel may be determined based on the type and frequency of the transmission signal. For example, the first semiconductor die 720 and the second semiconductor die 730 may transmit high-frequency signals through the pair of differential channels 840 in which the first capacitor 851 and the second capacitor 852 are disposed, and may transmit low-frequency signals or DC signals through the communication channel composed of the conductive wiring 890. That is, the first semiconductor die 720 and the second semiconductor die 730 may transmit relatively high-frequency and high-speed data signals, such as those used in Peripheral Component Interconnect express (PCIe), Universal Chiplet Interconnect express (UCIe), Universal Serial Bus (USB) 3.x, USB 4.0, Double Data Rate 4 (DDR4), DDR5, or Mobile Industry Processor Interface Camera Serial Interface/Display Serial Interface (MIPI CSI/DSI), through the pair of differential channels 840 in which the first capacitor 851 and the second capacitor 852 are disposed, and may transmit at least one of relatively low-frequency and low-speed control and status information signals-such as Inter-Integrated Circuit (I2C), Serial Peripheral Interface (SPI), General-Purpose Input/Output (GPIO), or Universal Asynchronous Receiver Transmitter (UART) signals-clock signals, serial data signals, operation setting signals, interrupt signals, power, ground, and DC signals through the communication channel composed of the conductive wiring 890. In some cases, the first semiconductor die 720 and the second semiconductor die 730 may transmit AC signals through the pair of differential channels 840 in which the first capacitor 851 and the second capacitor 852 are disposed, and transmit DC signals through the communication channel composed of the conductive wiring 890.

The semiconductor package 800 according to the present embodiment can select an optimal communication line based on the frequency of a transmission signal and transmit the transmission signal through the selected line by including the pair of differential channels 840, in which the first capacitor 851 and the second capacitor 852 are AC-coupled, and the communication channel in which conductive wiring 890 is DC-coupled. Accordingly, the semiconductor package 800 can transmit high-quality signals over a wide bandwidth without signal distortion and loss.

Further, the semiconductor package 800 according to the present embodiment may improve the compatibility of semiconductor dies with different frequency characteristics by including channels for various signal bands.

Further, the semiconductor package 800 according to the present embodiment may ensure compatibility without requiring redesign even when adding new chips or replacing existing chips in the package by including communication lines that support multiple bands. Thus, the system scalability of the semiconductor package 800 may be increased.

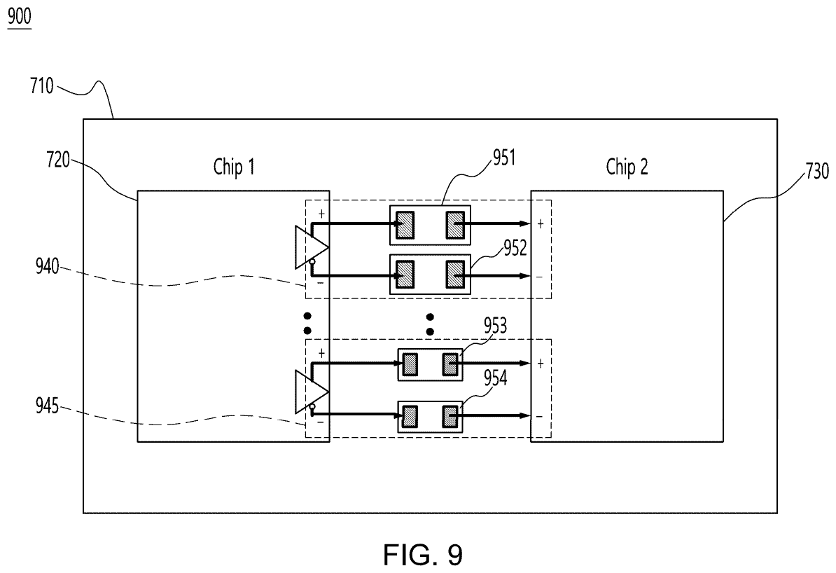

FIG. 9 is a top view of a semiconductor package, in which each of different pairs of differential channels includes capacitors having different capacitances, according to yet another embodiment of the present disclosure.

Referring to FIG. 9, a semiconductor package 900 according to the present embodiment may be configured such that capacitors with different capacitances are disposed in different pairs of differential channels based on the configuration of the semiconductor package 800 of FIG. 8. Accordingly, redundant descriptions of configurations that are substantially identical to those of the semiconductor package 100 of FIG. 1 and the semiconductor package 800 of FIG. 8 will be omitted.

A plurality of pairs of differential channels 940 and 945 may be disposed between the first semiconductor die 720 and the second semiconductor die 730. For example, as shown in FIG. 9, a first pair of differential channels 940 and a second pair of differential channels 945 may be disposed between the first semiconductor die 720 and the second semiconductor die 730. According to various embodiments of the present invention, at least one chip-to-chip communication channel, in which a conductive wiring (not shown) is DC-coupled, may also be disposed between the first semiconductor die 720 and the second semiconductor die 730. The chip-to-chip communication channel in which the conductive wiring (not shown) is DC-coupled may be substantially the same as the chip-to-chip communication channel composed of the conductive wiring 890 of FIG. 8.

Capacitors 951, 952, 953, and 954 may be disposed in the pairs of differential channels 940 and 945. For example, as shown in FIG. 9, a first capacitor 951 may be disposed in a first differential channel of the first pair of differential channels 940, a second capacitor 952 may be disposed in a second differential channel of the first pair of differential channels 940, a third capacitor 953 may be disposed in a first differential channel of the second pair of differential channels 945, and a fourth capacitor 954 may be disposed in the second differential channel of the second pair of differential channels 945.

Capacitors with different capacitances may be disposed in each of the different pairs of differential channels 940 and 945. For example, capacitances of the capacitors 951 and 952 disposed in the first pair of differential channels 940 may be different from capacitances of the capacitors 953 and 954 disposed in the second pair of differential channels 945. That is, the first capacitor 951 and the second capacitor 952 may have the same capacitance, the third capacitor 953 and the fourth capacitor 954 may have the same capacitance, and the first capacitor 951 and the third capacitor 953 may have different capacitances.

According to various embodiments of the present invention, a plurality of capacitors 951, 952, 953, and 954 with different capacitances may also be disposed in a single capacitor chip (not shown). The capacitor chip may include the plurality of capacitors 951 and 953 with different capacitances disposed on a single die. For example, the first capacitor 951, the second capacitor 952, the third capacitor 953, and the fourth capacitor 954 may be disposed in a single capacitor chip. The capacitor chip (not shown) may be disposed in substantially the same position as the capacitor chip 750 of FIG. 7. That is, the capacitor chip 750 shown in FIG. 7 may include the plurality of capacitors 951, 952, 953, and 954 with different capacitances shown in FIG. 9, and may be disposed in the semiconductor package 900.

By integrating the plurality of capacitors 951, 952, 953, and 954 with different capacitances into a single capacitor chip (not shown), a spacing between the capacitors 951, 952, 953, and 954 may be minimized. Accordingly, in the semiconductor package 900, a larger number of capacitors 951, 952, 953, and 954 can be integrated in the same area, thereby achieving higher capacitance within the same space and improving area efficiency of the package. In addition, by including the plurality of capacitors 951, 952, 953, and 954 in a single capacitor chip, and connecting each of the capacitors 951, 952, 953, and 954 to a different electrical path, the first semiconductor die 720 and the second semiconductor die 730 can transmit a chip-to-chip communication signal through various electrical paths according to the characteristics of the signal. In particular, since each of the plurality of capacitors 951, 952, 953, and 954 has a different capacitance, various electrical paths can be provided with only one capacitor chip, thereby improving the integration density of the semiconductor package 900.

The first semiconductor die 720 and the second semiconductor die 730 may selectively use the pairs of differential channels 940 and 945, in which the capacitors 951 and 953 with different capacitances are disposed. Specifically, the first semiconductor die 720 and the second semiconductor die 730 may selectively transmit signals through the chip-to-chip communication line, in which the capacitor 951 and 953 with an optimal capacitance is disposed, depending on the type and frequency of the transmission signal. For example, when the first and second semiconductor dies 720 and 730 transmit high-frequency signals, the first and second semiconductor dies 720 and 730 may select the communication line with an appropriate capacitance from among the communication lines with relatively small capacitances and transmit the signals to the selected communication line. That is, the first semiconductor die 720 and the second semiconductor die 730 may transmit data signals with relatively high frequency and speed, such as those used in PCIe, UCIe, USB 3.x, USB 4.0, DDR4, DDR5, or MIPI CSI/DSI, through channels with a relatively low capacitance, such as the second differential channels 945, may transmit signals with relatively moderate frequency and speed, such as SATA, Ethernet, Inter-IC Sound (I2S), or embedded Multi-Media Controller (eMMC)/Universal Flash Storage (UFS) signals, through differential channels with a capacitance between that of the first differential channels 940 and that of the second differential channels 945, and may transmit signals with relatively low frequency and speed, such as I2C signals, SPI signals, GPIO signals, or UART signals, through channels with a relatively high capacitance, such as the first differential channels 940.

According to various embodiments of the present invention, since the communication channel in which the conductive wiring (not shown) is DC-coupled is disposed between the first semiconductor die 720 and the second semiconductor die 730, the first semiconductor die 720 and the second semiconductor die 730 may also transmit signals with relatively low frequency and speed, such as I2C, SPI, GPIO, or UART signals, as well as DC signals, through the conductive wiring.

In the semiconductor package 900 according to the present embodiment, by including the pair of differential channels 940 and 945 in which the capacitor 951 and 953 with different capacitances are disposed, the semiconductor dies 720 and 730 disposed in the semiconductor package 900 may transmit and receive signals across various frequency bands, ranging from low frequencies to high frequencies.

Further, the semiconductor package 900 may minimize transmission signal bandwidth loss and support multi-band communication by including the communication channels with a capacitance optimized for each frequency band of the transmission signal. That is, the semiconductor dies 720 and 730 disposed in the semiconductor package 900 may simultaneously transmit and receive low-frequency data and high-frequency high-speed signals.

Further, the semiconductor package 900 according to the present embodiment may improve the compatibility of semiconductor dies with different frequency characteristics by including channels for various signal bands.

Further, the semiconductor package 900 according to the present embodiment may increase design flexibility and system scalability by including the communication channels that support multiple frequency bands. For example, when adding a new chip or replacing an existing chip within the package, compatibility may be ensured without requiring additional redesign.

According to any one of the means for solving the problems of the present invention, a semiconductor package includes a package substrate in which a chip-to-chip communication line is disposed between semiconductor dies, thereby enabling the integration of heterogeneous chips within a single package.

According to any one of the means for solving the problems of the present invention, a semiconductor package can improve electromagnetic interference (EMI) performance of chip-to-chip communication and enhance signal integrity by including a differential channel that performs the chip-to-chip communication.

According to any one of the means for solving the problems of the present invention, a semiconductor package can suppress noise in chip-to-chip communication and reduce signal distortion by including a capacitor that alternating current (AC)-couples different semiconductor dies.

According to any one of the means for solving the problems of the present invention, a semiconductor package can reduce electrical non-uniformity between differential channels and ensure the symmetry and stability of differential signals by including an AC coupling capacitor disposed in each differential channel.

According to any one of the means for solving the problems of the present invention, a semiconductor package can transmit high-quality signals without signal distortion or loss over a wide bandwidth by including a differential channel in which a capacitor is AC-coupled and a communication channel in which a conductive wiring is direct current (DC)-coupled.

According to any one of the means for solving the problems of the present invention, a semiconductor package can improve compatibility between semiconductor dies with different frequency characteristics and enhance flexibility in package design and system scalability by including channels for various signal bands.

The effects obtainable from the present invention are not limited to the effects mentioned above, and other effects not mentioned will be clearly understood by those skilled in the art to which the present invention pertains from the following description.

While the embodiments of the present invention have been described in detail above with reference to the accompanying drawings, the present invention is not necessarily limited to these embodiments, and various changes and modifications may be made without departing from the technical spirit of the present invention. Accordingly, the embodiments disclosed herein are to be considered descriptive and not restrictive of the technical spirit of the present invention, and the scope of the technical spirit of the present invention is not limited by these embodiments. Accordingly, the above-described embodiments should be understood to be exemplary and not limiting in any aspect. The scope of the present invention should be construed by the appended claims along with the full range of equivalents to which such claims are entitled.

What is claimed is:

1. A semiconductor package comprising:
a package substrate;
a first semiconductor die disposed on the package substrate;
a second semiconductor die disposed on the package substrate to be spaced apart from the first semiconductor die; and
at least one pair of differential channels connected to the first semiconductor die and the second semiconductor die,
wherein the at least one pair of differential channels include at least one first differential channel and at least one second differential channel, each of which transmits a signal with a different phase,
the at least one first differential channel includes a first capacitor,
the at least one second differential channel includes a second capacitor, and
each of the first capacitor and the second capacitor includes a first pad or bump connected to the first semiconductor die and a second pad or bump connected to the second semiconductor die.

2. The semiconductor package of claim 1, wherein the first capacitor and the second capacitor are disposed in the package substrate.

3. The semiconductor package of claim 2, further comprising a passivation layer disposed on the first capacitor and the second capacitor.

4. The semiconductor package of claim 2, wherein the first pad or bump and the second pad or bump are disposed on each of the first capacitor and the second capacitor, and
the first pad or bump is directly connected to a bump or pad disposed below the first semiconductor die, or the second pad or bump is directly connected to a bump or pad disposed below the second semiconductor die.

5. The semiconductor package of claim 1, further comprising an interposer disposed between the first and second semiconductor dies and the package substrate,
wherein the first capacitor and the second capacitor are disposed in the interposer.

6. The semiconductor package of claim 5, wherein the first capacitor and the second capacitor are embedded in the interposer, and
the interposer includes at least one of a first via formed to pass through between a bump or pad disposed below the first semiconductor die and the first pad, and a second via formed to pass through between a bump or pad disposed below the second semiconductor die and the second pad.

7. The semiconductor package of claim 1, wherein the first differential channel further includes at least one third capacitor connected in parallel with the first capacitor, and
the second differential channel further includes at least one fourth capacitor connected in parallel with the second capacitor.

8. The semiconductor package of claim 7, further comprising a plurality of switches each disposed between each of the first capacitor, the second capacitor, the third capacitor, and the fourth capacitor and the first semiconductor die or between each of the first capacitor, the second capacitor, the third capacitor, and the fourth capacitor and the second semiconductor die,
wherein the first capacitor and the second capacitor have the same capacitance,
the third capacitor and the fourth capacitor have the same capacitance, and
the first capacitor and the third capacitor have different capacitances.

9. The semiconductor package of claim 1, wherein a plurality of electrical paths are disposed between the first semiconductor die and the second semiconductor die, and
at least one of the plurality of electrical paths includes the at least one pair of differential channels.

10. The semiconductor package of claim 9, further comprising a capacitor chip in which a plurality of capacitors are disposed on a single die,
wherein the first capacitor and the second capacitor are disposed in the capacitor chip.

11. The semiconductor package of claim 9, wherein at least one of the plurality of electrical paths includes a conductive wiring, and
the conductive wiring direct current (DC)-couples the first semiconductor die and the second semiconductor die.

12. The semiconductor package of claim 9, wherein the at least one pair of differential channels are disposed as a plurality of pairs of differential channels, and
among the plurality of pairs of differential channels, at least two pairs of differential channels each include capacitors with different capacitances.

13. The semiconductor package of claim 12, wherein the first semiconductor die and the second semiconductor die selectively transmit and receive an alternating current (AC) signal through an optimal path among the plurality of pairs of differential channels, and
the optimal path is determined by a frequency of the AC signal and the capacitances.

14. The semiconductor package of claim 1, wherein the first semiconductor die and the second semiconductor die include a serializer and a deserializer, respectively.
